(19) United States
(12) Patent Application Publication
(10) Pub. No.: US 2017/0260438 A1
(43) Pub. Date: Sep. 14, 2017

(54) THERMALLY CONDUCTIVE SHEET

(71) Applicant: KITAGAWA INDUSTRIES CO., LTD., Aichi (JP)

(72) Inventors: Tomoyuki SUZUKI, Kasugai-shi, Aichi (JP); Yasuo KONDO, Kasugai-shi, Aichi (JP); Yasuhiro KAWAGUCHI, Kasugai-shi, Aichi (JP)

(21) Appl. No.: 15/531,880

(22) PCT Filed: Dec. 1, 2015
(86) PCT No.: PCT/JP2015/083709

§ 371 Date: May 31, 2017

(30) Foreign Application Priority Data
Dec. 2, 2014 (JP) 2014-243980

(51) Int. Cl. C09K 5/14; C08J 5/18; H01L 23/373; C08K 3/34

(52) U.S. Cl. CPC C09K 5/14; C08K 3/34; C08J 5/18; H01L 23/3737; C08K 2201/001; C08K 2201/005; C08J 2321/00

(57) ABSTRACT

A thermally conductive sheet has a high thermal conductivity and superior heat resistance. The thermally conductive sheet includes a rubber having flowability and a thermally conductive filler. The rubber is loaded with the thermally conductive filler and mixed and kneaded to form the thermally conductive sheet, and the thermally conductive filler includes a small particulate filler having an average particle size of not greater than 10 μm. The thermally conductive sheet has a thermal conductivity of not less than 1 W/m·K and an Asker C hardness after heating of not greater than 60.

### TECHNICAL FIELD

The present invention relates to a thermally conductive sheet.

### BACKGROUND ART

A thermally conductive sheet, which includes a base material, such as silicone rubber and synthetic rubber, loaded with a material having a high thermal conductivity, such as ceramics or carbon fibers, has been used conventionally for dissipation of heat generated from an electronic device or element and cooling (refer to Patent Document 1, for example).

### CITATION LIST

### Patent Literature

Patent Document 1: JP-A-02-16135

### TECHNICAL PROBLEM

A thermally conductive sheet requires a capability to include a large amount of a thermally conductive material as well as a flexibility. Thus, silicone, acrylic, urethane and the like in gel state, which have relatively high thermal resistance, have been used as a base material. However, if the thermally conductive sheet including a conventional gel material as a base material was used at a high temperature (e.g. not lower than 200° C.), the thermally conductive sheet experienced an increase in hardness and a mass reduction involving embrittlement, resulting in considerable decrease in life or reliability of the thermally conductive sheet.

### SUMMARY OF INVENTION

The thermally conductive sheet according to an aspect of the present invention was completed under the consideration of the problems described above. The object of the present invention is to provide a thermally conductive sheet having a high thermal conductivity and superior thermal resistance.

### Solution to Problem

As a result of diligent research to solve the problems described above, the present inventors discovered the following: a thermally conductive sheet, in which a rubber having flowability is loaded with a thermally conductive filler including a small particulate filler having an average particle size of not greater than 10 μm, exhibits a large thermal conductivity, and hardness increase can be suppressed while embrittlement can be prevented even if such a thermally conductive sheet is used for 100 hours at 275° C., for example. The present invention is based on this new finding.

According to an embodiment of the present invention, a thermally conductive sheet includes a rubber having flowability and a thermally conductive filler, wherein the rubber is loaded with the thermally conductive filler and mixed and kneaded to form the thermally conductive sheet; the thermally conductive filler includes a small particulate filler having an average particle size of not greater than 10 μm; and the thermally conductive sheet has a thermal conductivity of not less than 1 W/m·K and an Asker C hardness after heating of not greater than 60.

According to another embodiment of the present invention, a thermally conductive sheet includes a rubber having flowability and a thermally conductive filler, wherein the rubber is loaded with the thermally conductive filler and mixed and kneaded to form the thermally conductive sheet; the thermally conductive filler includes a mixture of a small particulate filler having an average particle size of not greater than 10 μm and a large particulate filler having an average particle size of not less than 50 μm and not greater than 100 μm at a mass ratio of the small particulate filler to the large particulate filler of from 1:0.5 to 1:2; and the thermally conductive sheet has a thermal conductivity of not less than 1 W/m·K and an Asker C hardness after heating of not greater than 60.

The details will be described in examples. According to embodiments of the present invention, a thermally conductive filler including a small particulate filler having an average particle size of not greater than 10 μm is used, and thus a thermally conductive sheet having a large thermal conductivity and excellent thermal resistance can be provided.

The present invention may be a configuration described below.

The rubber may be a silicone gel and the thermally conductive filler may include a mixture of the small particulate filler and a large particulate filler having an average particle size of not less than 50 μm and not greater than 100 μm at a mass ratio of the small particulate filler to the large particulate filler of from 1:0.5 to 1:1, and the small particulate filler and the large particulate filler are each silicon carbide.

Such a configuration can minimize a hardness change of the thermally conductive sheet between before and after the use at a high temperature.

The small particulate filler may be silicon carbide having an average particle size of not greater than 5.5 μm and a loading content of the thermally conductive filler may be not less than 40 vol. %.

Such a configuration can minimize a hardness change of the thermally conductive sheet between before and after the use at a high temperature.

### Advantageous Effects of Invention

According to the present invention, a thermally conductive sheet having a high thermal conductivity and superior heat resistance is provided.

### Description of the Embodiments

A thermally conductive sheet according to an embodiment of the present invention includes a rubber having a fluidity and a thermally conductive filler, and the rubber is loaded with the thermally conductive filler, mixed and kneaded to form the thermally conductive sheet.

Examples of the rubber having flowability include a silicone rubber in a liquid state, a silicone gel (a silicone rubber in a gel state), and ethyl ene-propyl ene-di ene rubber (EPDM).

Examples of the thermally conductive filler include silicon carbide, alumina, silica, silicon nitride, and boron nitride. Silicon carbide is preferable among these compounds.

The thermally conductive filler includes a small particulate filler having an average particle size of not greater than 10 μm. The small particulate filler having an average particle size of not greater than 5.5 μm is preferable from the viewpoint of reduction in hardness change between before and after the use at a temperature of from 175° C. to 250° C., for example.

Though the thermally conductive filler may consist only of a small particulate filler, the thermally conductive filler preferably includes a mixture of the small particulate filler and a large particulate filler having a particle size larger than that of the small particulate filler, because the thermal conductivity can be improved.

The large particulate filler preferably has an average particle size of not less than 50 μm and not greater than 100 μm. From the viewpoint of reduction in hardness change between before and after the use at a high temperature (i.e. hardness remains small even after the use at a high temperature), the mass ratio of the small particulate filler to the large particulate filler (small particulate filler:large particulate filler) is preferably from 1:0.25 to 1:2, particularly preferably from 1:0.5 to 1:1.

A loading content of the thermally conductive filler based on the volume of the thermally conductive sheet is preferably 35 vol. %, more preferably not less than 40 vol. %, and particularly preferably not less than 40 vol. % and not greater than 60 vol. %.

Example of a method for producing the thermally conductive sheet according to an embodiment of the present invention may include a method described below. The silicone rubber is loaded with a thermally conductive filler by mixing the rubber having flowability and the thermally conductive filler. Examples of the method for mixing the rubber and the thermally conductive filler include a method of mixing and kneading using an apparatus such as a vacuum defoaming mixer, extruding, and a method of mixing and kneading using a twin roller, kneader, and Banbury mixer. Among these methods, the method using a mixer is preferable from the viewpoint of handling improvement.

A retarder, antioxidant, flame retardant, plasticizer, colorant, and the like may be added to the rubber having flowability as necessary.

Next, a mixture of the rubber having flowability and the thermally conductive filler is formed. Examples of forming include various methods, such as a method using a machine (e.g. a coater, a calendering roller, an extruder and a press). Among these methods, the forming method using a coater is preferable because a thin sheet can be produced easily, the method is suited for mass production due to excellent productivity and the thickness precision can be easily controlled for the sheet thickness.

The thermally conductive sheet according to an embodiment of the present invention has a thermal conductivity of not less than 1 W/m·K, an Asker C hardness of not greater than 60 and an Asker C hardness after heating of not greater than 60. Details will be described in examples, but the thermally conductive sheet according to an embodiment of the present invention has an Asker C hardness of not greater than 60 after a heat-resistance test at 275° C. for 100 hours (corresponding to a heat resistance at 175° C. for 10 years), thereby satisfying the flexibility required for a thermally conductive sheet. The temperature condition of 175° C. corresponds to a junction temperature (the temperature at a chip interface of a semiconductor device) and time duration requirement of 10 years is a measure of durability assuming a typical industrial machine operation time.

Thus, the thermally conductive sheet according to an embodiment of the present invention is suitable for the use in a high temperature environment as well as the use as a conventional thermally conductive sheet. Such a thermally conductive sheet can be sufficiently applicable when a material for a semiconductor in a power semiconductor device is changed from silicon to silicon carbide, which has a high heat-resistance temperature.

### EXAMPLES

The embodiments of the present invention are described in detail using examples hereafter.

### 1. Study of Particle Size of Thermally Conductive Filler

(1) Preparation of Sheets Including Thermally Conductive Fillers with Different Particle Sizes
Preparation of sheet 1 and 2

Liquid silicone rubber “CY52-276 (trade name) manufactured by Dow Corning Toray Co., Ltd.” and a thermally conductive filler “silicon carbide, average particle size of 5.5 μm, GREENDENSIC (trade mark) #2500, manufactured by Showa Denko K.K.” were mixed and kneaded using a vacuum defoaming mixer, followed by forming using a coater to prepare a sheet having a thickness of 2 mm.

The thermally conductive filler was blended at 72.3 mass % per total mass of the sheet material and sheet 1 having a thermally conductive filler loading content of 45 vol. % of the sheet volume was obtained.

Sheet 2 having the thermally conductive filler loading content of 40 vol. % was obtained in the same manner as for sheet 1, except the blending ratio of the thermally conductive filler was 68.1 mass %.

Preparation of sheet 3 and 4

Sheet 3 having the thermally conductive filler loading content of 45 vol. % was obtained in the same manner as for sheet 1, except silicon carbide having an average particle size of 4 μm “GREENDENSIC (trade mark) #3000, manufactured by Showa Denko K.K.” was used at 72.3 mass %.

Sheet 4 having the thermally conductive filler loading content of 40 vol. % was obtained in the same manner as for sheet 3, except the blending ratio of the thermally conductive filler was 68.1 mass %.

Preparation of sheet 5 and 6

Sheet 5 having the thermally conductive filler loading content of 45 vol. % was obtained in the same manner as for sheet 1, except silicon carbide having an average particle size of 2 μm “GREENDENSIC (trade mark) #6000, manufactured by Showa Denko K.K.” was used at 72.3 mass %.

Sheet 6 having the thermally conductive filler loading content of 40 vol. % was obtained in the same manner as for sheet 5, except the blending ratio of the thermally conductive filler was 68.1 mass %.

Preparation of sheet A

Sheet A was prepared in the same manner as for sheet 1, except the thermally conductive filler was not blended and only liquid silicone rubber “CY52-276 (trade name), manufactured by Dow Corning Toray Co., Ltd.” was used.

Preparation of sheet B

Sheet B having the thermally conductive filler loading content of 40 vol. % was obtained in the same manner as for sheet 2, except silicon carbide having an average particle size of 40 μm “GREENDENSIC (trade mark) #320, manufactured by Showa Denko K.K.” was used at 68.1 mass %.

### (2) Thermal Resistance Evaluation Test

### Measurement of Initial Properties of Sheet

Using sheets 1 to 6, sheets A and B, samples of the size 100 mm×100 mm×10 mm were prepared by laminating. Thermal conductivity of each sample was measured by hot disc method in accordance with ISO 22007-2 using a measurement device “TPS-500, manufactured by Kyoto Electronics Manufacturing Co., Ltd.” and the results are shown in Table 1.

Initial hardness A1 (Asker C hardness, designated as “ASKER C” in Table) of each sample was measured by a method in accordance with JIS K7312, using Durometer ASKER C Type (manufactured by Kobunshi Keiki Co., Ltd.) and the measurement results are shown in Table 1. The evaluation results of the initial hardness A1 according to the criteria below are also shown in Table 1.

Fail: Hardness A1 is 0

Good: Hardness A1 is not less than 40 and not greater than 60

Excellent: Hardness A1 is not less than 1 and not greater than 39

### Thermal Resistance Test

Each sample was heated at 275° C. for 100 hours using a heating apparatus (ESPEC Desk-Top High Temp. Chamber STH120). The state of the sample after heating was visually observed and mass loss ratio [100× (mass before heating—mass after heating)/(mass before heating)] was calculated. Also, the hardness A2 (Asker C hardness) of the sample after heating was measured in the same manner as the initial hardness A1. The measurement values are listed in Table 1 and the evaluation results of the hardness A2 according to the criteria below are also shown in Table 1.

Fail: Hardness A2 is not less than 61

Good: Hardness A2 is not less than 40 and not greater than 60

Excellent: Hardness A2 is not less than 1 and not greater than 39

Furthermore, the difference (hardness change) between the hardness A2 after heating and the hardness A1 before heating was calculated for each sample and the evaluation results according to the criteria below are shown in Table 1.

Fail: The hardness change is not less than 16.

Marginal: The hardness change is not less than 10 and not greater than 15.

Good: The hardness change is not less than 5 and not greater than 9.

Excellent: The hardness change is less than 5

In the column of “Overall Assessment” in Table 1, the evaluation results according to the criteria whether the Asker C hardness after heating at 275° C. for 100 hours is not greater than 60 or not, as well as whether a thermal conductivity is not less than 1 W/m·K, and an Asker C hardness is not greater than 60 are shown. Specifically, a sheet having a thermal conductivity of not less than 1 W/m·K, and the initial hardness A1 and the hardness A2 are both not greater than 60 is rated as Good, and a sheet that does not meet these criteria is rated as Fail.

TABLE 1

| | | | Initial material properties | | | Material properties after thermal resistance test | | | | |
|---|---|---|---|---|---|---|---|---|---|---|
| | | | | Hardness A1 | | Hardness A2 | | Hardness change | | |
| | Particle | Loading | Thermal | (ASKER C) | | (ASKER C) | | (A2-A1) | | Overall |
| Sheet | size | content | conductivity | Measurement | Eval- | Measurement | Eval- | Hardness | Eval- | assess- |
| No. | (μm) | (vol. %) | (W/m · K) | value | uation | value | uation | change | uation | ment |
| A | — | 0 | 0.18 | 0 | Fail | Measurement | — | — | — | Fail |
| | | | | | | Failed | | | | |
| B | 40 | 40 | 1.28 | 33 | Excellent | 65 | Fail | 32 | Fail | Fail |
| 1 | 5.5 | 45 | 1.28 | 40 | Good | 41 | Good | 1 | Excellent | Good |
| 2 | | 40 | 1.00 | 31 | Excellent | 29 | Excellent | −2 | Excellent | Good |
| 3 | 4 | 45 | 1.31 | 42 | Good | 43 | Good | 1 | Excellent | Good |
| 4 | | 40 | 1.09 | 30 | Excellent | 10 | Excellent | 0 | Excellent | Good |
| 5 | 2 | 45 | 1.36 | 44 | Good | 50 | Good | 6 | Good | Good |
| 6 | | 40 | 1.04 | 30 | Excellent | 37 | Excellent | 7 | Good | Good |

### (3) Results and Discussion

For the sheets 1 to 6 after the thermal resistance test, no glassification (embrittlement) of the sheet surface was observed and the mass loss ratio was not greater than 1.1%. However, for the sheets A and B after the thermal resistance test, the sheet surface showed glassification and the mass loss ratio was as large as 2.7% or greater.

The sheets 1 to 6, which included the thermally conductive filler having the average particle size of from 2 μm to 5.5 μm, exhibited the thermal conductivity as large as 1.00 W/m·K or greater, the Asker C hardness after the thermal resistance test of from 29 to 50 and the hardness change of not greater than 7. These are good results.

On the other hand, though the sheet B including the thermally conductive filler having an average particle size of 40 μm exhibited a large thermal conductivity, it exhibited the Asker C hardness of 65 after the thermal resistance test and the hardness change of 32. In addition, the sheet A that did not include the thermally conductive filler exhibited a small thermal conductivity and hardness compared to sheets 1 to 6 and sheet B, and it was impossible to measure the hardness after the thermal resistance test.

The results show that a thermally conductive sheet having a large thermal conductivity and excellent thermal resistance can be provided by loading a thermally conductive filler having an average particle size of from 2 μm to 5.5 μm, but a sheet including only a thermally conductive filler having an average particle size of 40 μm does not exhibit sufficient thermal resistance and a sheet including no thermally conductive filler fails to exhibit thermal conductivity.

### 2. Study of Mixing Amount of Small Particulate Filler and Large Particulate Filler

### (1) Preparation of Sheet Including Small Particulate Filler and Large Particulate Filler

### Preparation of Sheets 7 to 30

Liquid silicone rubber “CY52-276 (trade name) manufactured by Dow Corning Toray Co., Ltd.”, a small particulate filler “silicon carbide, average particle size of 5.5 μm, GREENDENSIC (trade mark) #2500, manufactured by Showa Denko K.K.” and a large particulate filler “silicon carbide, average particle size of 63 μm, GREENDENSIC (trade mark) F 180, manufactured by Showa Denko K.K.” were mixed and kneaded using a vacuum defoaming mixer, followed by forming using a coater to prepare a sheet having a thickness of 2 mm.

For sheets 7 to 9, a mixture of the small particulate filler and the large particulate filler, which were mixed at a ratio of 1:1/4 (mass ratio), was included at 72.3 mass %, 68.1 mass % and 63.4 mass %, so that the loading content of the thermally conductive filler was 45 vol. %, 40 vol. % and 35 vol. %, respectively.

For sheets 10 to 12, a mixture of the small particulate filler and the large particulate filler, which were mixed at a ratio of 1:1/2 (mass ratio), was included at 72.3 mass %, 68.1 mass % and 63.4 mass %, so that the loading content of the thermally conductive filler was 45 vol. %, 40 vol. % and 35 vol. %, respectively.

For sheets 13 to 16, a mixture of the small particulate filler and the large particulate filler, which were mixed at a ratio of 1:2/3 (mass ratio), was included at 77.5 mass %, 76.1 mass % 68.1 mass % and 63.4 mass %, so that the loading content of the thermally conductive filler was 52 vol. %, 50 vol. %, 40 vol. % and 35 vol. %, respectively.

For sheets 17 to 19, a mixture of the small particulate filler and the large particulate filler, which were mixed at a ratio of 1:1 (mass ratio), was included at 79.5 mass %, 68.1 mass % and 63.4 mass %, so that the loading content of the thermally conductive filler was 55 vol. %, 40 vol. % and 35 vol. %, respectively.

For sheets 20 to 24, a mixture of the small particulate filler and the large particulate filler, which were mixed at a ratio of 1:3/2 (mass ratio), was included at 79.5 mass %, 76.1 mass % 68.1 mass %, 63.4 mass %, and 58.0 mass %, so that the loading content of the thermally conductive filler was 55 vol. %, 50 vol. %, 40 vol. %, 35 vol. %, and 30 vol. %, respectively.

For sheets 25 to 27, a mixture of the small particulate filler and the large particulate filler, which were mixed at a ratio of 1:2 (mass ratio), was included at 79.5 mass %, 68.1 mass % and 63.4 mass %, so that the loading content of the thermally conductive filler was 55 vol. %, 40 vol. % and 35 vol. %, respectively.

For sheets 28 to 30, a mixture of the small particulate filler and the large particulate filler, which were mixed at a ratio of 1:3 (mass ratio), was included at 82.6 mass %, 76.1 mass % and 74.7 mass %, so that the loading content of the thermally conductive filler was 60 vol. %, 50 vol. % and 48 vol. %, respectively.

### (2) Thermal Resistance Evaluation Test

### Measurement of Initial Physical Properties of Sheet

Using sheets 7 to 30, samples of the size 100 mm×100 mm×10 mm were prepared by laminating. Thermal conductivity of each sample was measured by hot disc method in accordance with ISO 22007-2 using a measurement device “TPS-500, manufactured by Kyoto Electronics Manufacturing Co., Ltd.” and the results are shown in Table 2.

Hardness A1 (Asker C hardness, initial hardness) of each sample was measured by a method in accordance with JIS K7312, using Durometer ASKER C Type (manufactured by Kobunshi Keiki Co., Ltd.) and the measurement results are shown in Table 2. The evaluation results of the initial hardness A1 according to the criteria below are also shown in Table 2.

Good: Hardness A1 is not less than 40 and not greater than 60

Excellent: Hardness A1 is not less than 1 and not greater than 39

### Thermal Resistance Test

Each sample was heated at 275° C. for 100 hours using a heating apparatus (ESPEC Desk-Top High Temp. Chamber STH120). The state of the sample after heating was visually inspected. Also, the hardness A2 (Asker C hardness) of the sample after heating was measured in the same manner as the initial hardness A1. The measurement values are listed in Table 2 and the evaluation results of the hardness A2 according to the criteria below are also shown in Table 2.

Fail: Hardness A2 is not less than 61

Good: Hardness A2 is not less than 40 and not greater than 60

Excellent: Hardness A2 is not less than 1 and not greater than 39

Furthermore, the difference (hardness change) between the hardness A2 after heating and the hardness A1 before heating was calculated for each sample and the evaluation results according to the criteria below are shown in Table 2. Table 2 also shows data for sheets 1 and 2, which were prepared and studied in 1.

Fail: The hardness change is not less than 16

Marginal: The hardness change is not less than 10 and not greater than 15

Good: The hardness change is not less than 5 and not greater than 9

Excellent: The hardness change is less than 5

In the column of “Overall Assessment” in Table 2, the evaluation results according to the criteria whether the Asker C hardness after heating at 275° C. for 100 hours is not greater than 60 or not, as well as whether a thermal conductivity is not less than 1 W/m·K, and an Asker C hardness is not greater than 60 are shown. Specifically, a sheet having a thermal conductivity of not less than 1 W/m·K, having an initial hardness A1 of not greater than 60 and a hardness A2 of not greater than 60 is rated as Good.

TABLE 2

| | Small | | | | | | | | | |
|---|---|---|---|---|---|---|---|---|---|---|
| | particle: | | Initial physical properties | | | Physical properties after thermal resistance test | | | | |
| | large | | | Hardness A1 | | Hardness A2 | | Hardness change | | |
| | particle | Loading | Thermal | (ASKER C) | | (ASKER C) | | (A2-A1) | | |
| Sheet | (mass | content | conductivity | Measurement | | Measurement | | Hardness | | Overall |
| No. | ratio) | (vol. %) | (W/m · K) | value | Evaluation | value | Evaluation | change | Evaluation | assessment |
| 1 | 1:0 | 45 | 1.3 | 45 | Good | 50 | Good | 5 | Good | Good |
| 2 | | 40 | 1.0 | 31 | Excellent | 29 | Excellent | −2 | Excellent | Good |
| 7 | 1:0.25 | 45 | 1.3 | 33 | Excellent | 38 | Excellent | 5 | Good | Good |
| 8 | | 40 | 1.2 | 26 | Excellent | 26 | Excellent | 0 | Excellent | Good |
| 9 | | 35 | 1.0 | 21 | Excellent | 19 | Excellent | −2 | Excellent | Good |
| 10 | 1:0.5 | 45 | 1.4 | 31 | Excellent | 30 | Excellent | −1 | Excellent | Good |
| 11 | | 40 | 1.3 | 28 | Excellent | 25 | Excellent | −3 | Excellent | Good |
| 12 | | 35 | 1.0 | 21 | Excellent | 17 | Excellent | −4 | Excellent | Good |
| 13 | 1:2/3 | 52 | 1.9 | 51 | Good | 54 | Good | 3 | Excellent | Good |
| 14 | | 50 | 1.7 | 42 | Good | 45 | Good | 4 | Excellent | Good |
| 15 | | 40 | 1.2 | 26 | Excellent | 30 | Excellent | 4 | Excellent | Good |
| 16 | | 35 | 1.0 | 21 | Excellent | 25 | Excellent | 4 | Excellent | Good |
| 17 | 1:1 | 55 | 2.2 | 42 | Good | 44 | Good | 2 | Excellent | Good |
| 18 | | 40 | 1.3 | 29 | Excellent | 12 | Excellent | 3 | Excellent | Good |
| 19 | | 35 | 1.2 | 18 | Excellent | 21 | Excellent | 3 | Excellent | Good |
| 20 | 1:1.5 | 55 | 2.2 | 48 | Good | 50 | Good | 2 | Excellent | Good |
| 21 | | 50 | 1.7 | 28 | Excellent | 34 | Excellent | 6 | Good | Good |
| 22 | | 40 | 1.4 | 20 | Excellent | 25 | Excellent | 5 | Good | Good |
| 23 | | 35 | 1.2 | 19 | Excellent | 30 | Excellent | 11 | Marginal | Good |
| 24 | | 30 | 1.1 | 12 | Excellent | 26 | Excellent | 14 | Marginal | Good |
| 25 | 1:2 | 55 | 2.2 | 48 | Good | 50 | Good | 2 | Excellent | Good |
| 26 | | 40 | 1.4 | 21 | Excellent | 22 | Excellent | 1 | Excellent | Good |
| 27 | | 35 | 1.2 | 20 | Excellent | 35 | Excellent | 15 | Marginal | Good |
| 28 | 1:3 | 60 | 2.7 | 53 | Good | 50 | Good | −3 | Good | Good |
| 29 | | 50 | 1.8 | 38 | Excellent | 40 | Good | 2 | Excellent | Good |
| 30 | | 48 | 1.7 | 34 | Excellent | 36 | Excellent | 2 | Excellent | Good |

### (3) Results and Discussion

For sheets 7 to 30, after the thermal resistance test, no glassification (embrittlement) of the sheet surface was observed. The sheets 7 to 30 exhibited the thermal conductivity as large as 1.00 W/m·K or greater, the Asker C hardness after the thermal resistance test of from 19 to 54 and the hardness change of not greater than 15. The results show that the present invention can provide a thermally conductive sheet having a high thermal conductivity and superior heat resistance.

Sheets including a small particulate filler, which was silicon carbide having an average particle size of not greater than 5.5 μm, and a thermally conductive filler at a loading content of not less than 40 vol. % were sheets 1 and 2, sheets 7 and 8, sheets 10 and 11, sheets 13 to 15, sheets 17 to 19, sheets 20 to 22, sheets 25 and 26, and sheets 28 to 30. For these sheets, the hardness change was from −3 to 6. The results show that the hardness change can be minimized if the configuration above is used.

Also, sheets 10 to 19, in which the mixing ratio of the small particulate filler to the large particulate filler was 1:1/2 to 1, exhibited small hardness change of −4 to 4. The results show that the hardness change can be minimized if the configuration above is used.

1-5. (canceled)

6. A thermally conductive sheet comprising a rubber having flowability and a thermally conductive filler, wherein
the rubber is loaded with the thermally conductive filler and mixed and kneaded to form the thermally conductive sheet,
the thermally conductive filler comprises a small particulate filler having an average particle size of not greater than 10 μm,
the thermally conductive sheet has a thermal conductivity of not less than 1 W/m·K and an Asker C hardness after heating of not greater than 60,
the small particulate filler is silicon carbide, and
a loading content of the thermally conductive filler is not less than 35 vol. % and not greater than 60 vol. %.

7. The thermally conductive sheet according to claim 6, wherein
the rubber is a silicone gel, and the thermally conductive filler comprises a mixture of the small particulate filler and a large particulate filler having an average particle size of not less than 50 μm and not greater than 100 μm at a mass ratio of the small particulate filler to the large particulate filler of from 1:0.5 to 1:1, and the small particulate filler and the large particulate filler are each silicon carbide.

8. A thermally conductive sheet comprising a rubber having flowability and a thermally conductive filler, wherein
the rubber is loaded with the thermally conductive filler and mixed and kneaded to form the thermally conductive sheet,
the thermally conductive filler comprises a mixture of a small particulate filler having an average particle size of not greater than 10 μm and a large particulate filler having an average particle size of not less than 50 μm and not greater than 100 μm at a mass ratio of the small particulate filler to the large particulate filler of from 1:0.5 to 1:2,
the thermally conductive sheet has a thermal conductivity of not less than 1 W/m·K and an Asker C hardness after heating of not greater than 60, and
a loading content of the thermally conductive filler is not less than 35 vol. % and not greater than 60 vol. %.

9. The thermally conductive sheet according to claim 8, wherein
the rubber is a silicone gel, and
the small particulate filler and the large particulate filler are each silicon carbide and the thermally conductive filler comprises a mixture of the small particulate filler and the large particulate filler at a mass ratio of the small particulate filler to the large particulate filler of from 1:0.5 to 1:1.

10. The thermally conductive sheet according to claim 6, wherein the small particulate filler is silicon carbide having an average particle size of not greater than 5.5 μm and a loading content of the thermally conductive filler is not less than 40 vol. %.

11. The thermally conductive sheet according to claim 8, wherein the small particulate filler is silicon carbide having an average particle size of not greater than 5.5 μm and a loading content of the thermally conductive filler is not less than 40 vol. %.
